(19) United States
(12) Patent Application Publication
(10) Pub. No.: US 2003/0218896 A1
(43) Pub. Date: Nov. 27, 2003

(54) Combined memory

(76) Inventors: Harry Q. Pon, Carmichael, CA (US); Mark D. Winston, El Dorado Hills, CA (US)

Correspondence Address: FISH & RICHARDSON, PC, 4350 LA JOLLA VILLAGE DRIVE, SUITE 500, SAN DIEGO, CA, 92122, US

(21) Appl. No.: 10/152,014

(22) Filed: May 22, 2002

(51) Int. Cl. G11C 5/06

(52) U.S. Cl. 365/63

(57) ABSTRACT

A memory includes a cross point memory and a second memory. The cross point memory includes a memory element disposed at a cross point. The memory element exists in a plurality of states. The second memory includes a second memory element that exists in a plurality of states.

### BACKGROUND

This disclosure relates to combining cross point memory with other memory.

Modern digital equipment often stores large amounts of data that can be referred to as “sequential” data. Sequential data is serial in nature and can be arranged in a relatively orderly fashion. For example, digital cameras store sequential image pixel data, while digital music players store sequential music data. For sequential data, relatively large sequences of adjacent data points (i.e., data points that represent neighboring times or locations) can be sequentially written to and read from adjacent memory locations.

In addition to storing sequential data, most digital equipment also requires the storage of other types of data. For example, both relatively long-lived randomly accessed code execution data and relatively short-lived temporary data (for example, partial products generated during multiplication) are stored by digital equipment. To provide for the storage of different kinds of data, many designers often include multiple memory devices in a single piece of digital equipment.

### DESCRIPTION OF DRAWINGS

FIG. 1 is a side block diagram view of a memory package including an integrated cross point memory.

FIG. 2 is a top view of an integrated memory including a cross point memory.

FIG. 3 is a sectional view of the integrated memory of FIG. 2 taken along section 3-3 of FIG. 2.

FIG. 4 is a sectional view of the integrated memory of FIG. 2 taken along section 4-4 of FIG. 2.

FIG. 5 is a process flow for producing the integrated memory of FIG. 2.

FIG. 6 is a top view of another integrated memory including a cross point memory.

FIG. 7 is a sectional view of the integrated memory of FIG. 6 taken along section 6-6 of FIG. 6.

FIG. 8 is a sectional view of the integrated memory of FIG. 6 taken along section 7-7 of FIG. 6.

FIG. 9 is a side view of a memory package including a stacked cross point memory.

FIG. 10 is a top view of a stacked die memory including a cross point memory.

FIG. 11 is a sectional view of another integrated memory.

FIG. 12 is a block diagram of a personal digital assistant including a combined cross point/flash memory

FIG. 13 is a block diagram of a network terminal including a combined cross point/flash memory.

FIG. 14 is a block diagram of a cellular phone including a combined cross point/flash memory.

Like reference symbols in the various drawings indicate like elements. To assist understanding, the various drawings are not drawn to scale.

### DETAILED DESCRIPTION

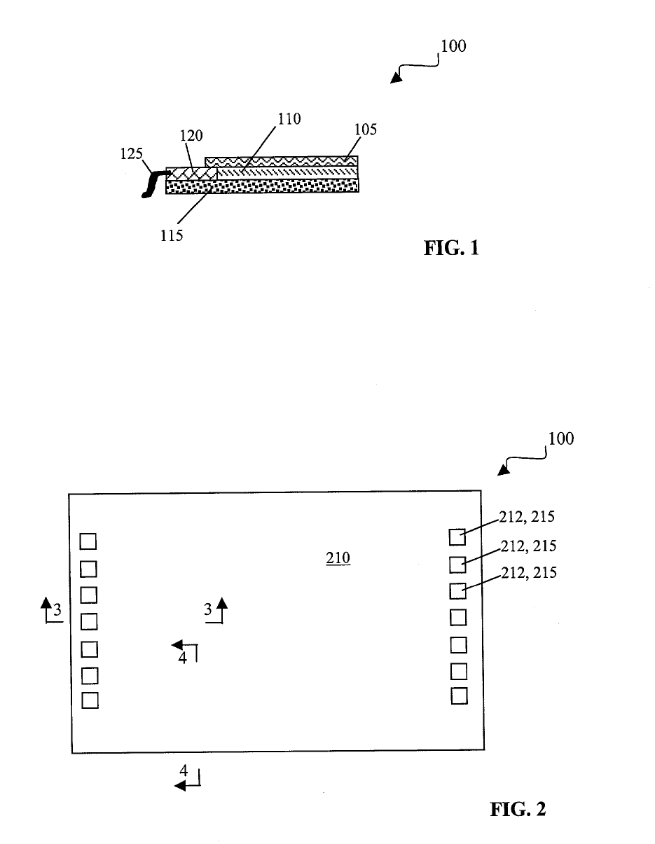

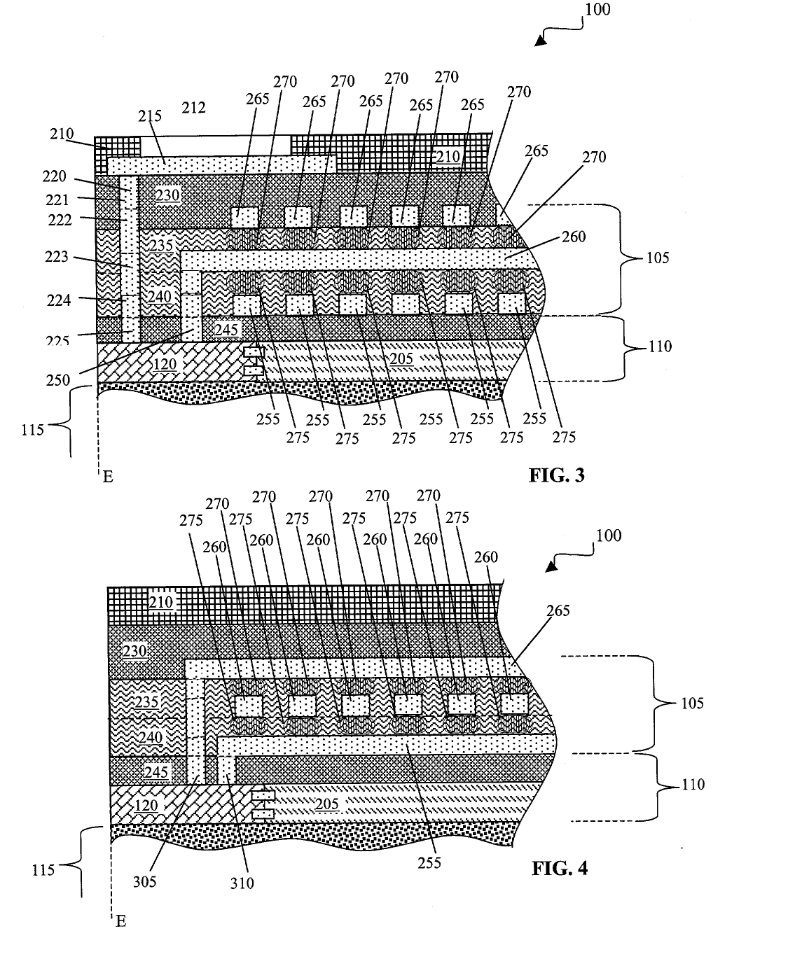

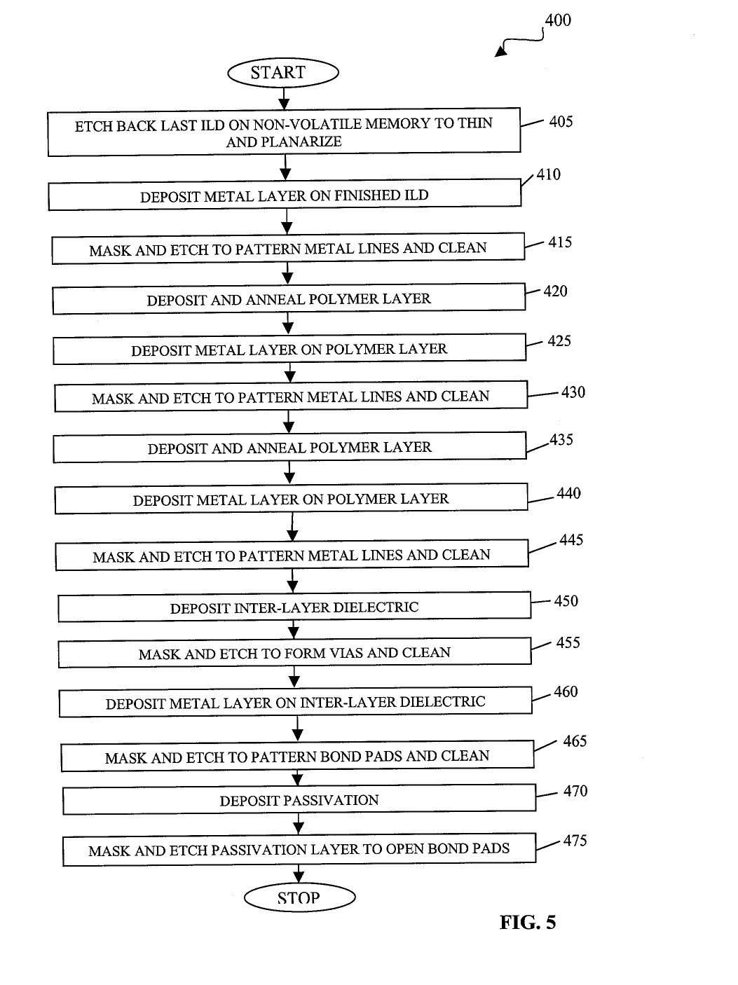

Referring to FIGS. 1-4, a combined integrated memory 100 includes a cross point memory 105 integrated with a flash memory 110 above a single silicon die 115. A joint memory control circuit 120 is also formed on die 115 and controls both cross point memory 105 and flash memory 110. Data and addressing information for both memory 105 and memory 110 are provided through a shared set of I/O connectors 125. By combining cross point memory 105 and flash memory 110, increased amounts of data, including sequential data, may be stored with little, if any, increase in the total memory footprint and the length and/or number of routings in a piece of digital equipment.

Referring in particular to FIGS. 2-4, flash memory 110 includes flash memory elements 205 and is formed on silicon die 115. Silicon die 115 also includes the joint memory control circuit 120 that controls read and write operations for both cross point memory 100 and flash memory 110. By using a single memory control circuit 120 to read to and write from both cross point memory 105 and flash memory 110, the cost relative to storage capacity of integrated memory 100 is reduced.

Integrated memory 100 is covered by a silicon nitride passivation layer 210 that defines holes 212 to expose bond pads 215. Bond pads 215 provide I/O connections 125 and are each electrically connected to joint memory control circuit 120 by an electrically conducting via 220 formed from aluminum vias 221, 222, 223, 224, 225. Vias 221-225 are formed at different times during processing. Via 220 passes through an insulating interlayer dielectric (ILD) 230, a first polymer memory layer 235, a second polymer memory layer 240, and another interlayer dielectric (ILD) 245. Interlayer dielectrics 230 and 245 may be formed from, for example, silica-based or polymeric interlayer dielectric materials.

Interlayer 245 is formed above memory control circuit 120 and flash memory elements 205. A trio of vias 250, 305, and 310 pass through interlayer 245 to make electrical connections between cross point memory 105 and memory control circuit 120. Memory control circuit 120 is thus capable of reading from and writing to individual memory elements in both cross point memory 105 and flash memory 110 in response to instructions provided to integrated memory 100 through bond pads 215.

Cross point memory 105 includes three successively orthogonal arrays of parallel lines 255, 260, and 265 separated by two intermittently contiguous cross-point memory polymer layers 235 and 240. Cross-point memory polymer layers 235 and 240 extend to an edge E of the integrated memory 100 and may be deposited in a single spin coating step. Cross-point memory polymer layers 235 and 240 may be made from, for example, a polyvinylidine fluoride polymer. Polymer layer 235 forms an array of cross-point memory elements 270 between orthogonal lines 260 and 265, and polymer layer 240 forms an array of cross-point memory elements 275 between orthogonal lines 255 and 260. Memory elements 270 and 275 polarize mainly by reorienting in response to the application of a potential difference across the corresponding pairs of orthogonal lines 260, 265 and 255, 260 by memory control circuit 120 during writing. For example, a polyvinylidine fluoride polymer may reorient in response to an electric field of 20 to 70 V/μm, although this is not a limitation of the present invention. Memory elements 270, 275 then maintain at least a portion of the induced reorientation polarization after the potential difference is removed to provide a historical record or “memory” of the write event.

In use, a memory controller or a processor writes to cross point memory 105 in combined memory 100 by presenting bus commands to memory control circuit 120 through bond pad 215. The bus commands may include a data bit that identifies one of cross point memory 105 and flash memory 110 for read/write operations. Since the operational requirements, including, for example, write voltages, for controlling cross point memory 105 and flash memory 110 are similar, memory control circuit 120 may be shared by cross point memory 105 and flash memory 110.

In the event that cross point memory 105 is identified, memory control circuit 120 then selects and biases a pair of orthogonal lines 260, 265 or 255, 260 with a sufficient potential and for a sufficient time to polarize the corresponding memory element 270 or 275. At least a portion of this polarization is maintained without refreshing by the selected memory element 270 or 275 after memory control circuit 120 removes the bias.

When reading memory element 270 or 275, memory control circuit 120 receives bus commands requesting that it determine if the portion of the polarization is maintained by the selected memory element 270 or 275. In response, memory control circuit 120 determines the existence of any residual polarization in the selected memory element 270 or 275 and relays this information to the controller or processor, along with bus commands that indicate the source of the data. In this manner, any kind of data, including sequential data, may be stored in the cross-point memory 105 of combined memory 100.

Referring also to FIG. 5, a process 400 for forming integrated memory 100 starts with the etching and planarization of interlayer dielectric 245 on silicon die 210 (405). A metal layer is then deposited above interlayer dielectric 245 by, for example, sputtering, evaporation, or electrochemical deposition (410), and then masked and etched to form orthogonal lines 255 (415). A glue metal layer may be added beneath this and all metal layers to secure the metal layers to the substrate.

A cross-point memory polymer solution is then spun coat above the patterned metal layer and annealed to form polymer layer 240 (420). Next, another metal layer is deposited (425). This metal layer then is masked and etched to form orthogonal lines 260 (430). Another cross-point memory polymer solution is then spun coat above the patterned metal layer and annealed to form polymer layer 235 (435). A third metal layer is then deposited (440) and masked and etched to form orthogonal lines 260 (445).

Interlayer dielectric 230 is then deposited on cross-point memory polymer layer 260 by, for example, spin coating, vapor deposition, or another process (450) and then masked and etched to form the vias (455). A fourth metal layer is deposited above interlayer dielectric 230 (460) and then masked and etched to form bond pads 115 and any other surface features (465). Passivation 105 is then deposited (470) and masked and etch to form holes 110 (475)

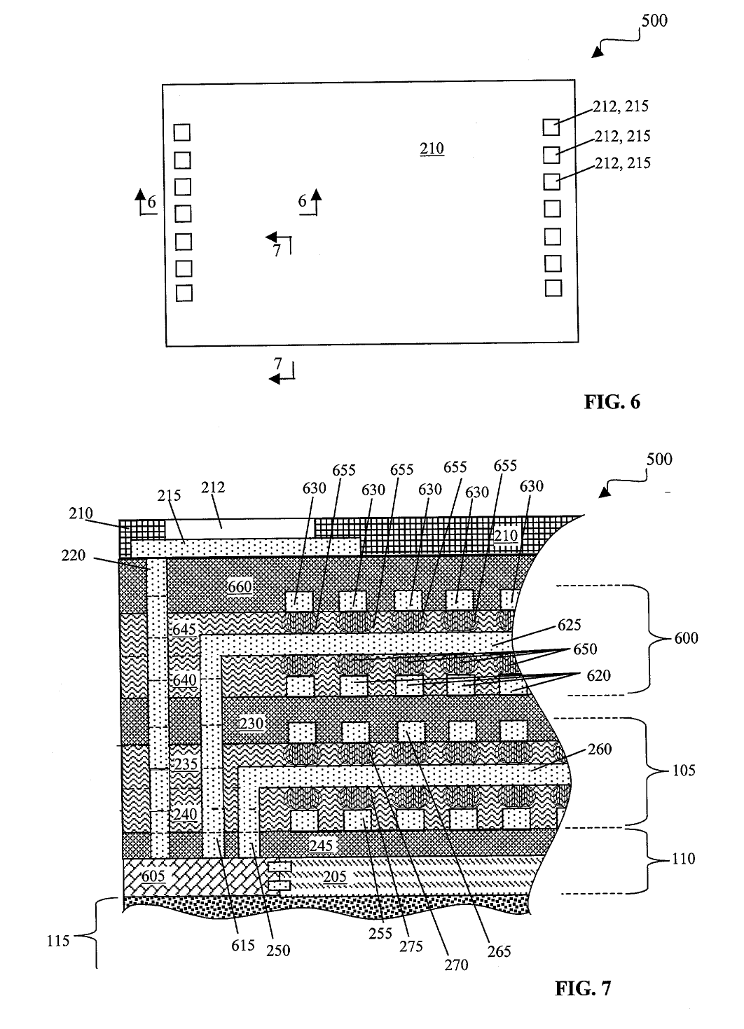

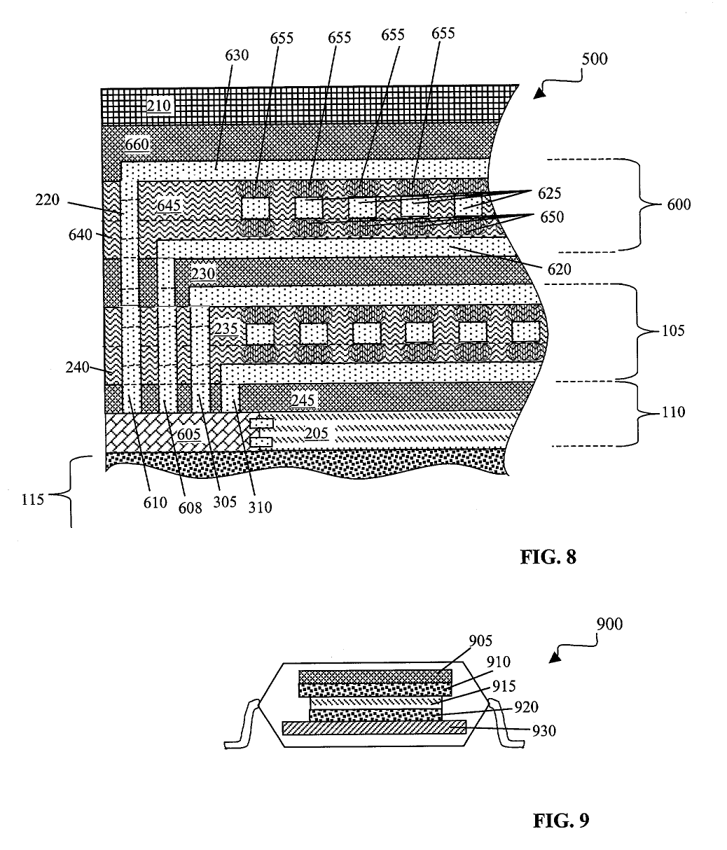

Referring to FIGS. 6, 7, and 8, another implementation of a combined, integrated memory 500 includes a second cross point memory 600 integrated with the first cross point memory 105 and the flash memory 110. A joint memory control circuit 605 controls read and write operations for the first cross point memory 105, the second cross point memory 600, and the elements 205 of the flash memory 110. By combining cross point memories 105 and 600 with flash memory 110 in a single, integrated body, increased amounts of data may be stored with little, if any increase in the total memory footprint and the length and/or number of routings in a piece of digital equipment.

In combined memory 500, interlayer dielectric 245 passes an additional trio of vias 608, 610, and 615 to electrically connect second cross point memory 600 and memory control circuit 605 so that memory control circuit 605 is able to read from and write to second cross point memory 600. Cross point memory 600 includes three successively orthogonal arrays of parallel lines 620, 625, and 630 separated by two intermittently contiguous cross-point memory polymer layers 640 and 645. Polymer layer 640 forms an array of cross-point memory elements 650 between orthogonal lines 620 and 625, and polymer layer 645 forms an array of cross-point memory elements 655 between orthogonal lines 625 and 630. An interlayer dielectric layer 660 is formed above second cross point memory 600.

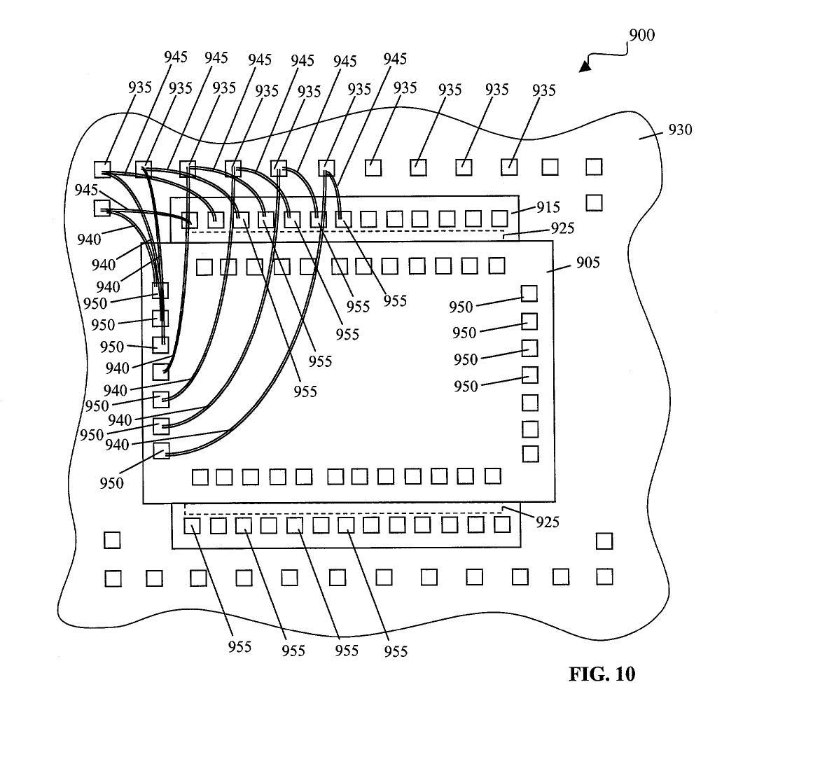

Referring to FIGS. 9 and 10, a combined, stacked memory 900 is formed by stacking a cross-point memory 905 formed on a first die 910 on top of a flash memory 915 formed on a second die 920. Second die 920 includes a joint memory control circuit 925 (shown in dashed lines in FIG. 10 to indicate that control circuit 925 is on second die 920). Cross point memory 905 and flash memory 915 are secured to each other and to a substantially planar mount element 930 that includes a number of bond pads 935 for forming electrical connections between cross-point memory 905 and flash memory 915. In particular, each bond pad 935 is electrically connected to a cross-point wire 940 and a flash memory wire 945. Cross-point wire 940 and flash memory wire 945 may be uninsulated and may cross each other on different planes. Cross-point wires 940 extend to bond pads 950 on cross-point memory 905, while flash memory wires 945 extend to bond pads 955 on flash memory 915. Cross-point memory 905 is thus joined by external wires 940 and 945 to flash memory 915 and memory control circuit 925 for read and write operations. The cost advantage provided by using a single memory control circuit 925 is maintained, and additional process flexibility is provided in that a manufacturer may substitute or omit parts as desired even at a relatively late stage in the manufacturing process.

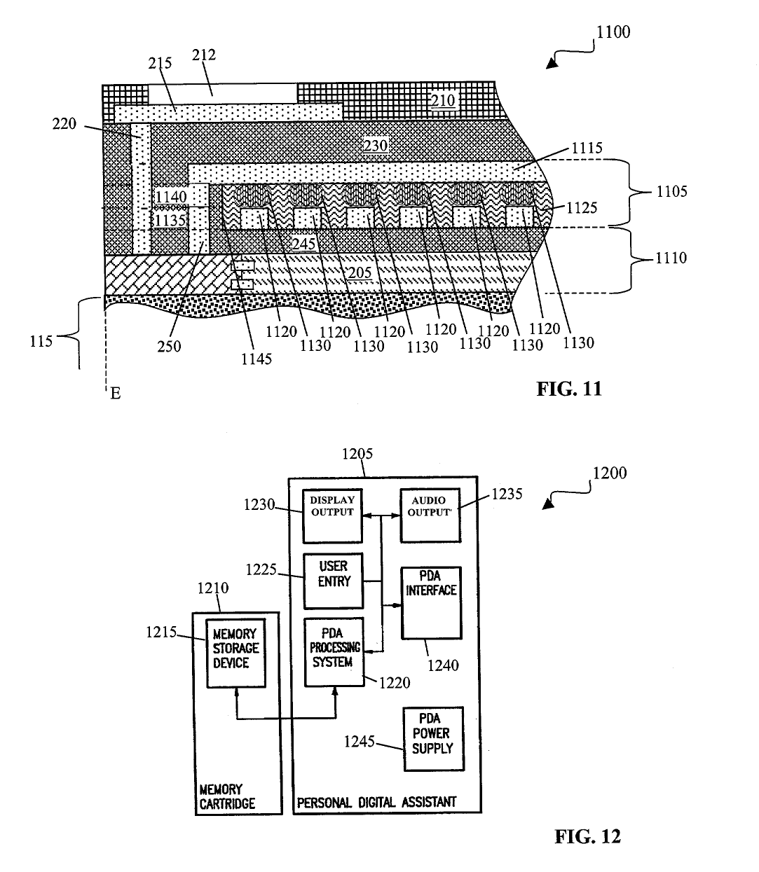

Referring to FIG. 11, a combined, integrated memory 1100 includes a cross point memory 1105 integrated with a flash memory 1110. Cross point memory 1105 includes two substantially orthogonal arrays of parallel lines 1115 and 1120 separated by a cross-point memory polymer layer 1125. Polymer layer 1125 forms an array of cross-point memory elements 1130 between lines 1115 and 1120.

Integrated memory 1100 also includes a pair of interlayer dielectric layers 1135 and 1140 that bound an outer edge 1145 of polymer layer 1125 SO that polymer layer 1125 does not extend to edge E of the integrated memory 1100. Polymer layer 1125 is thus sealed within integrated memory 1100 and further isolated from, for example, environmental conditions. Also, vias 220 and 250 are encased within relatively nonpolarizable interlayer dielectric material to simplify the electrical behavior of integrated memory 1100.

Referring to FIG. 12, a personal digital system 1200 includes a personal digital assistant 1205 and a detachable memory cartridge 1210. Detachable memory cartridge 1210 includes a combined cross point/flash memory 1215 for high density data storage. Personal digital assistant 1205 includes a processing system 1220 for reading data from and writing data to memory cartridge 1210. Personal digital assistant 1205 also includes an input device 1225 for receiving user entries, a display output 1230 and an audio output 1235 for outputting visual and audio signals to a user, and a PDA interface 1240 for interfacing with another device such as, for example, a personal computer (not shown). Personal digital assistant 1205 is powered by a power supply 1245.

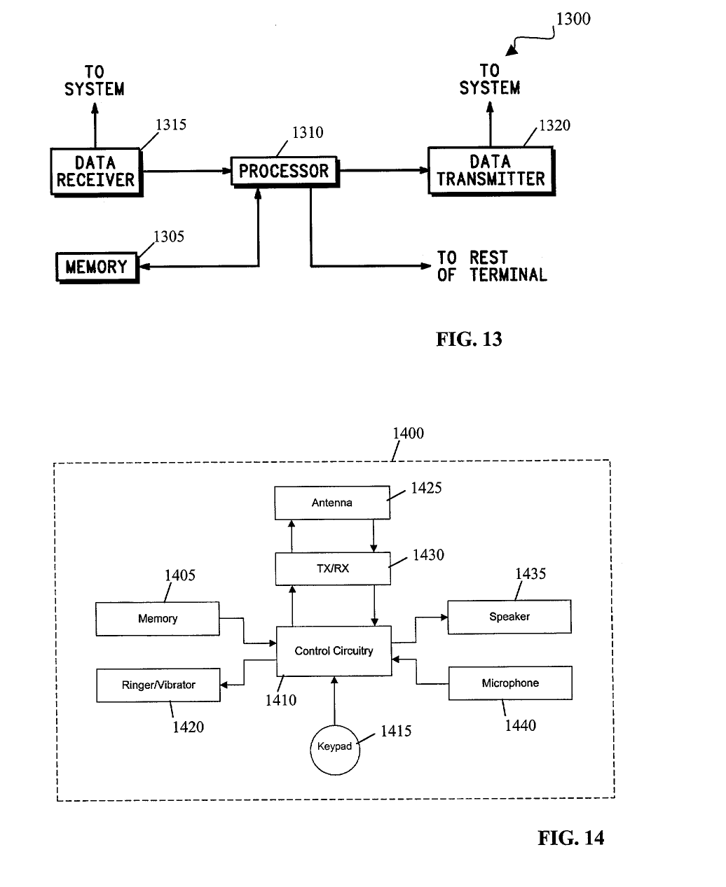

Referring to FIG. 13, a network terminal 1300 for exchanging information with a network system includes a combined cross point/flash memory 1305 that serves to reduce the total memory footprint in network terminal 1300. Network terminal 1300 may define, for example, a personal computer, a network router, or a hub. Network terminal 1300 also includes a processor 1310 for controlling the operation of network terminal 1300 including reading from and writing to combined memory 1305, a data receiver 1315 for receiving information from the network system, and a data transmitter 1320 for transmitting information to the network system.

Referring to FIG. 14, a cellular phone 1400 includes a combined cross point/flash memory 1405 that serves to reduce the total memory footprint in cellular phone 1400 and the size of cellular phone 1400. Cellular phone 1400 also includes control circuitry 1410 for controlling the operation of cellular phone 1400 including reading from and writing to combined memory 1405, an input keypad 1415 for dialing, a ringer/vibrator 1420 for notifying a user of an incoming call, an antenna 1425 and a transmitter/receiver 1430 for broadcasting and receiving electromagnetic signals that encode, for example, a conversation, a speaker 1435 for relaying, for example, incoming portions of the conversation to a user, and a microphone 1440 for transducing, for example, the user's responses in the conversation.

Other modifications may be made. For example, vias may be made from other conductors, including the metals tungsten and copper. The constituent materials of vias and interlayers may be mixed within a single combined memory. Electrical connections within and to the combined memory may be made by any of a number of different techniques, including, for example, ball grid arrays and tape automated bonding. The cross point memory may be combined with any of a number of different memory devices, including one or more cross point memories, SRAM, and DRAM. Multiple cross point memory layers may be combined with other memories in either integrated or stacked die devices. Another flash, another non-volatile memory, or a volatile memory may be stacked with a cross point memory in either the integrated or separated die device. The stacking order may be switched. A wide range of materials and methods may be used to form the structures described herein. For example, copolymers of polyvinylidene fluoride and other polymers (for example, trifluoroethylene) may be used to form a cross-point polymer memory layer. Other cross-point memory materials may be used, including ceramics. The cross point memory materials may store data using different physical mechanisms, including magnetic polarization.

Accordingly, other implementations are within the scope of the following claims.

What is claimed is:

1. A memory comprising:
a cross point memory including
a first conductor,
a second conductor skew to the first conductor, the second conductor being closest to the first conductor at a cross point, and
a memory element disposed between the first conductor and the second conductor at the cross point, the memory element to exist in a plurality of states; and
a second memory including a second memory element to exist in a plurality of states, wherein the cross point memory and the second memory are in a stacked orientation and share data inputs and outputs.

2. The memory of claim 1 wherein the cross point memory comprises:
a substantially coplanar array of substantially parallel first conductors; and
a substantially coplanar array of substantially parallel second conductors arranged such that a projection of the second conductors onto the first conductors is substantially orthogonal to the first conductors.

3. The memory of claim 1 wherein the memory element comprises a polarizable element configured to exist in a plurality of polarization states.

4. The memory of claim 3 wherein the polarizable element comprises a polarizable polymer.

5. The memory of claim 4 wherein the polarizable polymer comprises polyvinyldifluoride.

6. The memory of claim 4 wherein the polarizable polymer comprises a copolymer of trifluorethylene.

7. The memory of claim 3 wherein the polarizable element extends to an edge of the cross point memory.

8. The memory of claim 1 wherein the memory element is configured to exist in two determinable states and to switch between determinable states in response to an electric field between the first conductor and the second conductor.

9. The memory of claim 1 wherein the second memory comprises a non-volatile memory.

10. The memory of claim 1 wherein the cross point memory is on a first die and the second memory is on a second die.

11. The memory of claim 1 wherein the cross point memory and the second memory are integrated onto a single die.

12. The memory of claim 1 further comprising memory control circuitry configured to selectably exchange electronic signals between the host system and one of the cross point memory and the second memory.

13. The memory of claim 1 wherein the cross point memory is above the second memory.

14. A method of forming a memory comprising:
positioning a cross-point memory and a second memory in a stacked orientation; and
sharing a data input and a data output with the cross-point memory and the second memory.

15. The method of claim 14 wherein stacking a cross-point memory with a second memory comprises integrating the cross-point memory onto a single die with the second memory.

16. The method of claim 14 wherein stacking a cross-point memory with a second memory further comprises electrically connecting memory control circuitry to the cross-point memory and the second memory.

17. The method of claim 16 wherein electrically connecting the memory control circuitry further comprises forming the memory control circuitry on the single die with the cross-point memory and the second memory.

18. The method of claim 14 wherein:
the cross-point memory is on a first die;
the second memory is on a second die; and
stacking the cross-point memory with the second memory comprises stacking the first die with the second die.

19. A system comprising:
a stacked memory including:
a cross point memory including
a first conductor,
a second conductor skew to the first conductor, the second conductor being closest to the first conductor at a cross point, and
a memory element disposed between the first conductor and the second conductor at the cross point, the memory element being configured to exist in a plurality of determinable states; and
a second memory including a second memory element being configured to exist in a plurality of determinable states; and
a processor for reading data from and writing data to the stacked memory.

20. The system of claim 19 further comprising:
a data receiver configured to receive information; and
a data transmitter configured to transmit information.

21. The system of claim 19 wherein the system comprises a personal computer.

22. An apparatus, comprising:
a first crosspoint memory having a memory element disposed at a cross point between first and second conductors and programmable to a plurality of states; and
a flash memory in a stacked orientation to the first crosspoint memory and commonly sharing data terminals.

23. The apparatus of claim 22, further including a memory control circuit to control read and write operations to the first crosspoint memory and to the flash memory.

24. The apparatus of claim 23, further including a second crosspoint memory integrated with the first cross point memory and the flash memory, wherein the first crosspoint memory, the second crosspoint memory and the flash memory are controlled by the memory control circuit.

25. The apparatus of claim 23, wherein the memory control circuit supplies a programming bias to polarize the memory element.

26. A method of forming a memory device, comprising:
planarizing a first dielectric layer on a silicon substrate;
depositing a first metal layer on the first dielectric layer;
forming a first polymer layer above the first metal layer;
depositing a second metal layer on the first polymer layer;
forming a second polymer layer above the second metal layer;
depositing a third metal layer on the second polymer layer;
depositing a second dielectric layer on the third metal layer; and
depositing a fourth metal layer on the second dielectric layer.

27. The method of claim 26, further including adding a passivation layer to protect the memory device.

28. The method of claim 26, further including pattering the fourth metal layer to form bond pads.

29. The method of claim 26, further including forming a cross-point memory element in the first polymer layer between orthogonal lines formed from the first and second metal layers.

30. The method of claim 29, further including programming the memory element by supplying bias potentials on the first and second metal layers.

31. An apparatus, comprising:
a crosspoint memory having a memory element disposed at a cross point between first and second conductors and programmable to a plurality of states; and
a nonvolatile memory joined to the crosspoint memory and commonly sharing data terminals.

32. The apparatus of claim 31 wherein the crosspoint memory is joined to the nonvolatile memory in a stacked orientation.

33. The apparatus of claim 31, further including a memory control circuit to control read and write operations to the crosspoint memory and to the nonvolatile memory.

34. The apparatus of claim 33, wherein the crosspoint memory and the nonvolatile memory are controlled by the memory control circuit.
